(19) United States
(12) Patent Application Publication
(10) Pub. No.: US 2024/0401885 A1
(43) Pub. Date: Dec. 5, 2024

(54) VAPOR CHAMBER

(71) Applicant: FURUKAWA ELECTRIC CO., LTD., Tokyo (JP)

(72) Inventors: Takahiro BANZAI, Tokyo (JP); Hirofumi AOKI, Tokyo (JP); Kunihiro DOTE, Tokyo (JP); Kenya KAWABATA, Tokyo (JP); Toshiyuki ANDO, Tokyo (JP)

(73) Assignee: FURUKAWA ELECTRIC CO., LTD., Tokyo (JP)

(21) Appl. No.: 18/802,923

(22) Filed: Aug. 13, 2024

Related U.S. Application Data
(63) Continuation of application No. PCT/JP2023/007218, filed on Feb. 28, 2023.

(30) Foreign Application Priority Data
Feb. 28, 2022 (JP) 2022-030043

(51) Int. Cl. F28D 15/04

(52) U.S. Cl. CPC F28D 15/04

(57) ABSTRACT

The vapor chamber including a container having a cavity portion formed inside, and having a first surface to which a heating element is to be thermally connected and a second surface facing the first surface, a first wick portion provided on the first surface, a second wick portion provided on the second surface, a support portion having a third wick portion, protruding in a direction to connect the first surface and the second surface in the inside of the container, a working fluid enclosed in the cavity portion, and a vapor flow path through which the working fluid in a gas phase is to flow, the vapor flow path being provided in the cavity portion, in which one end of the third wick portion is integrated with the first wick portion, and another end of the third wick portion is integrated with the second wick portion.

### CROSS REFERENCE TO RELATED APPLICATIONS

The present application is a continuation application of International Patent Application No. PCT/JP2023/007218 filed on Feb. 28, 2023, which claims the benefit of Japanese Patent Application No. 2022-030043, filed on Feb. 28, 2022. The contents of these applications are incorporated herein by reference in their entirety.

### BACKGROUND

### Technical Field

The present disclosure relates to a vapor chamber that is excellent not only in resistance to pressure from an external environment, but also in resistance to pressure from an inside of the vapor chamber, and thereby has excellent deformation resistance even when a temperature of a usage environment rises.

### Background

Electronic components such as semiconductor devices mounted on electric/electronic equipment increase the amount of heat generation due to high-density mounting and the like accompanying high functionality, and in recent years, cooling of the electronic components has become more important. Further, due to miniaturization of electronic equipment, heating elements of electronic components may be disposed in narrow spaces. As a cooling unit for heating elements of electronic components or the like disposed in narrow spaces, a vapor chamber (planar heat pipe) including a flat container may be used.

Further, from a perspective of miniaturization and weight reduction of a vapor chamber, it is required to reduce the wall thickness of a container of the vapor chamber. On the other hand, since the inside of the container is decompressed, if the thickness of the container becomes thinner, there is a risk that the container may be deformed by pressure from the external environment such as atmospheric pressure. If the container is deformed, flow characteristics of a working fluid are deteriorated, and the heat transport properties of the vapor chamber may be deteriorated. Thus, a columnar support portion (support pillar portion) may be provided inside of the container of the vapor chamber to maintain the internal space of the container.

As a vapor chamber provided with the support portion inside of the container to maintain the internal space of the container against the pressure from the external environment, a vapor chamber is proposed, which includes a wick body that is disposed in a space sealed by an upper plate, a lower plate, and a plurality of side walls, is in contact with the upper plate and the lower plate, and has a plurality of first wick portions having straight-line portions, and pillars that are disposed in the space and in contact with the upper plate and the lower plate, in which the pillars are each disposed between the straight-line portions in the two adjacent first wick portions of the plurality of first wick portions by being spaced from the straight-line portions (International Publication No. WO 2017/104819). In International Publication No. WO 2017/104819, a vapor chamber is proposed which has resistance to the pressure from the external environment by including the pillars that are in contact with the upper plate and the lower plate, and can secure a vapor flow path even if the thickness of the container is reduced.

On the other hand, vapor chambers may be used under a high temperature environment (for example, under an environment of 100° C. or higher). Since a working fluid such as water is enclosed in a vapor chamber, the pressure inside of the vapor chamber rises when the ambient temperature becomes high, and the vapor chamber may expand. When the vapor chamber expands, the flow characteristics of the working fluid is deteriorated to deteriorate the heat transport properties of the vapor chamber, and thermal connectivity with a heating element that is an object to be cooled may be deteriorated.

### SUMMARY

The present disclosure is related to providing a vapor chamber having excellent deformation resistance even when a temperature of a usage environment rises by being able to prevent a vapor chamber from expanding by not only having resistance to pressure from an external environment but also excellent in resistance to pressure from an inside of the vapor chamber.

The gist of the present disclosure is as follows.

[1] A vapor chamber including
a container having a cavity portion formed inside, and having a first surface to which a heating element is to be thermally connected and a second surface facing the first surface,
a first wick portion provided on the first surface in an inside of the container;
a second wick portion provided on the second surface in the inside of the container,
a support portion having a third wick portion protruding in a direction to connect the first surface and the second surface in the inside of the container,
a working fluid enclosed in the cavity portion, and
a vapor flow path through which the working fluid in a gas phase is to flow, the vapor flow path being provided in the cavity portion,
wherein one end of the third wick portion is integrated with the first wick portion, and another end of the third wick portion is integrated with the second wick portion.

[2] The vapor chamber as set forth in [1], wherein a porosity of the first wick portion in a part that overlaps with the support portion in plan view is smaller than a porosity of the first wick portion in a part that does not overlap with the support portion in plan view.

[3] The vapor chamber as set forth in [1] or [2], wherein a porosity of the second wick portion in a part that overlaps with the support portion in plan view is smaller than a porosity of the second wick portion in a part that does not overlap with the support portion in plan view.

[4] The vapor chamber as set forth in any one of [1] to [3], wherein the first wick portion, the second wick portion, and the third wick portion are sintered bodies of powder containing metal powder.

[5] The vapor chamber as set forth in any one of [1] to [4], wherein the support portion comprises the third wick portion.

[6] The vapor chamber as set forth in any one of [1] to [5], wherein the support portion is formed of a protruding part protruding in a direction of the cavity portion from the first surface or a protruding part protruding in the direction of the cavity portion from the second surface, and the third wick portion covering a surface of the protruding part.

[7] The vapor chamber as set forth in [6], wherein the protruding part is solid.

[8] The vapor chamber as set forth in any one of [1] to [7], wherein a porosity of the first wick portion in a part that does not overlap with the support portion in plan view is smaller than a porosity of the second wick portion in a part that does not overlap with the support portion in plan view.

[9] The vapor chamber as set forth in any one of [1] to [8], wherein a porosity of the first wick portion in a part that does not overlap with the support portion in plan view is smaller than a porosity of the third wick portion.

[10] The vapor chamber as set forth in any one of [1] to [9], wherein a porosity of the third wick portion is smaller than a porosity of the second wick portion in a part that does not overlap with the support portion in plan view.

[11] The vapor chamber as set forth in any one of [1] to [10], wherein a porosity of the third wick portion differs from a porosity of the first wick portion or a porosity of the second wick portion.

[12] The vapor chamber as set forth in any one of [1] to [10], wherein a porosity of the third wick portion differs from a porosity of the first wick portion, and differs from a porosity of the second wick portion.

In the above-described aspect, the first surface that is a surface to which the heating element is to be thermally connected and the second surface facing the first surface are main surfaces of the container. In the present disclosure, “plan view” means a state of viewing at a position facing the first surface that is the main surface of the container.

In an aspect of the vapor chamber of the present disclosure, the one end of the third wick portion of the support portion is integrated with the first wick portion provided on the first surface, and the other end of the third wick portion of the support portion is integrated with the second wick portion provided on the second surface, whereby the first surface and the second surface of the container are both fixed to the support portion. Consequently, according to the aspect of the vapor chamber of the present disclosure, the vapor chamber not only has resistance to the pressure from the external environment, but also is excellent in resistance to the pressure from the inside of the vapor chamber, and thereby the vapor chamber can be prevented from expanding, so that it is possible to obtain the vapor chamber having excellent deformation resistance even when a temperature of a usage environment rises.

Further, according to the aspect of the vapor chamber of the present disclosure, the one end of the third wick portion of the support portion is integrated with the first wick portion provided on the first surface, and the other end of the third wick portion of the support portion is integrated with the second wick portion provided on the second surface, whereby interface formation between the wick portion on the second surface and the wick portion of the support portion is prevented, and interface formation between the wick portion on the first surface and the wick portion of the support portion is also prevented. Accordingly, reflux characteristics of the working fluid in a liquid phase from the wick portion on the second surface to the wick portion of the support portion and reflux characteristics of the working fluid in a liquid phase from the wick portion of the support portion to the wick portion on the first surface are improved, and therefore, heat transport properties of the vapor chamber are improved.

According to the aspect of the vapor chamber of the present disclosure, the porosity of the first wick portion in the part that overlaps with the support portion in plan view is smaller than the porosity of the first wick portion in the part that does not overlap with the support portion in plan view, whereby a connection area of the third wick portion of the support portion and the first wick portion can be made in an increased mode, so that integration of the third wick portion and the first wick portion is enhanced, and it is possible to obtain more excellent deformation resistance.

According to the aspect of the vapor chamber of the present disclosure, the porosity of the second wick portion in the part that overlaps with the support portion in plan view is smaller than the porosity of the second wick portion in the part that does not overlap with the support portion in plan view, whereby a connection area of the third wick portion of the support portion and the second wick portion can be made in an increased mode, so that integration of the third wick portion and the second wick portion is enhanced, and it is possible to obtain more excellent deformation resistance.

According to the aspect of the vapor chamber of the present disclosure, the first wick portion, the second wick portion, and the third wick portion are sintered bodies of powder containing metal powder, and thereby integration of the third wick portion and the first wick portion and integration of the third wick portion and the second wick portion are reliably improved.

According to the aspect of the vapor chamber of the present disclosure, the support portion is composed of the third wick portion, and thereby the reflux characteristics of the working fluid in a liquid phase from the second wick portion to the first wick portion are further improved.

According to the aspect of the vapor chamber of the present disclosure, the support portion is formed of the protruding part protruding in the direction of the cavity portion from the first surface or the protruding part protruding in the direction of the cavity portion from the second surface, and the third wick portion covering the surface of the protruding part, and thereby it is possible to further improve the deformation resistance of the vapor chamber while improving the reflux characteristics of the working fluid in a liquid phase from the second wick portion to the first wick portion.

### BRIEF DESCRIPTION OF THE DRAWINGS

FIG. 1 is a perspective view explaining an outline of a vapor chamber according to a first embodiment of the present disclosure;

FIG. 2 is a sectional side view explaining an outline of an internal structure of the vapor chamber according to the first embodiment of the present disclosure;

FIG. 3 is an explanatory view showing a reflux current of a working fluid in a liquid phase of the vapor chamber according to the first embodiment of the present disclosure;

FIG. 4 is a sectional side view explaining an outline of an internal structure of a vapor chamber according to a second embodiment of the present disclosure;

FIG. 5 is a sectional side view explaining an outline of an internal structure of a vapor chamber according to a third embodiment of the present disclosure;

FIG. 6 is a sectional side view explaining an outline of an internal structure of a vapor chamber according to a fourth embodiment of the present disclosure; and

FIG. 7 is a sectional side view explaining an outline of an internal structure of a vapor chamber according to a fifth embodiment of the present disclosure.

### DETAILED DESCRIPTION

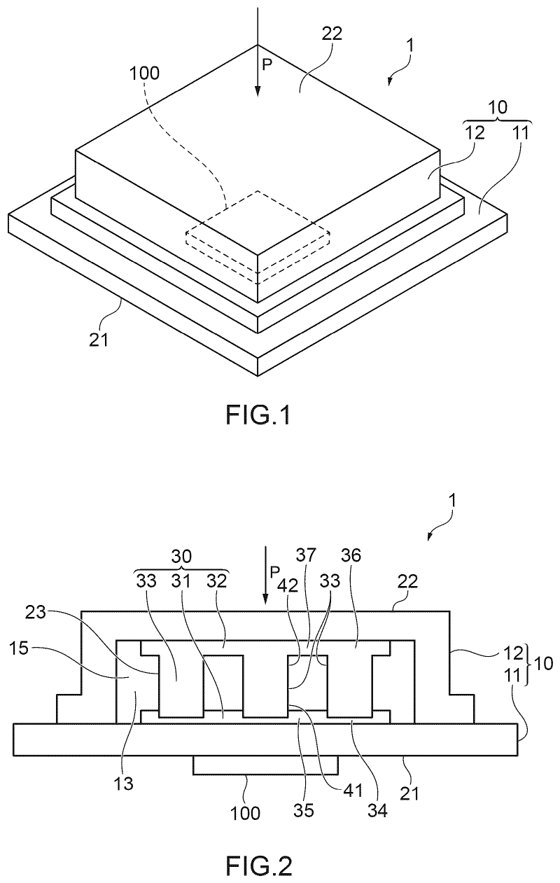

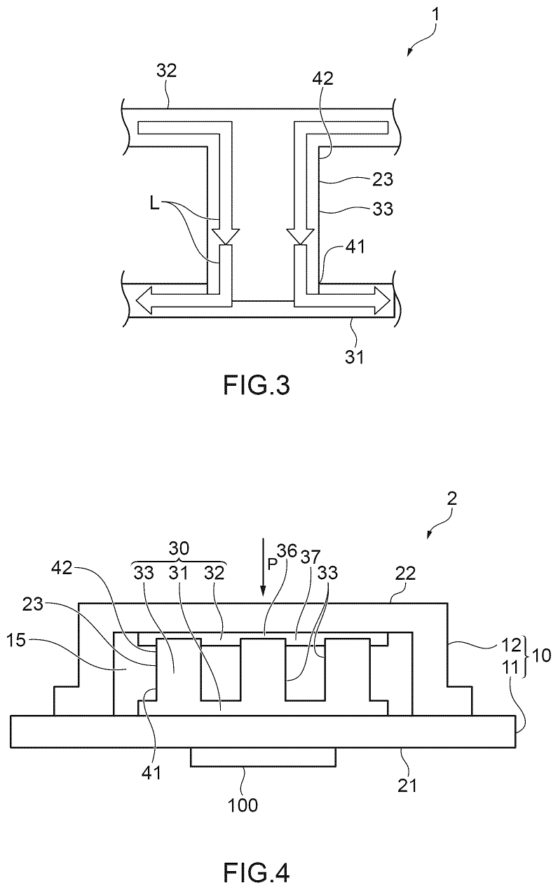

Hereinafter, a vapor chamber according to the present disclosure will be described. First, a vapor chamber according to a first embodiment of the present disclosure will be described with use of the drawings. FIG. 1 is a perspective view explaining an outline of the vapor chamber according to the first embodiment of the present disclosure. FIG. 2 is a sectional side view explaining an outline of an internal structure of the vapor chamber according to the first embodiment of the present disclosure. FIG. 3 is an explanatory view showing a reflux current of a working fluid in a liquid phase of the vapor chamber according to the first embodiment of the present disclosure. Note that an arrow P in each of the drawings indicates a direction of plan view.

As shown in FIG. 1, a vapor chamber 1 according to the first embodiment of the present disclosure has a container 10 inside of which a cavity portion is formed by stacking two plate-shaped bodies facing each other, that is, one plate-shaped body 11 and another plate-shaped body 12 that faces the one plate-shaped body 11. A shape of the container 10 is a thin plate shape, and therefore, the container 10 is a planar container. The one plate-shaped body 11 has a first surface 21 that is a first main surface, and the other plate-shaped body 12 has a second surface 22 that is a second main surface. Accordingly, the container 10 has the first surface 21 that is the first main surface, and the second surface 22 that faces the first surface 21 and is the second main surface.

In the vapor chamber 1, a shape in plan view is a quadrangular shape for convenience of explanation. The shape in plan view of the vapor chamber 1 is not particularly limited, and, for example, a shape having a bending portion, a shape having an indentation portion, a shape having a protruding portion, a polygonal shape other than a quadrangular shape, a circular shape, an elliptical shape, a shape having a straight-line portion and a bending portion, and the like are cited.

As shown in FIG. 2, the vapor chamber 1 includes the container 10 that is the container 10 having a cavity portion 13 formed inside by stacking the one plate-shaped body 11 and the other plate-shaped body 12 facing the one plate-shaped body 11, and has the first surface 21 to which a heating element 100 is thermally connected and the second surface 22 facing the first surface 21, a working fluid (not illustrated) enclosed in the cavity portion 13, and a vapor flow path 15 through which the working fluid in a gas phase is to flow, the vapor flow path 15 being provided in the cavity portion 13. The cavity portion 13 that is an internal space of the container 10 is a sealed space decompressed by degassing. The heating element 100 is thermally connected to an outer surface of the first surface 21.

In the vapor chamber 1, a wick structure 30 is provided in the cavity portion 13. The wick structure 30 is a member having a capillary force. The wick structure 30 has a first wick portion 31 provided on the first surface 21 in an inside of the container 10, a second wick portion 32 provided on the second surface 22 in the inside of the container 10, and a third wick portion 33 that protrudes in a direction to connect the first surface 21 and the second surface 22 in the inside of the container 10.

The first wick portion 31 is provided on an inner surface of the first surface 21, and extends throughout the substantially entire first surface 21 along the inner surface of the first surface 21. The second wick portion 32 is provided on an inner surface of the second surface 22 and extends throughout the substantially entire second surface 22 along the inner surface of the second surface 22.

In the vapor chamber 1, the third wick portion 33 is a support portion 23 for maintaining the internal space of the container 10. Further, the third wick portion 33 is also a member that causes the working fluid in a liquid phase to flow back to the first wick portion 31 from the second wick portion 32. The third wick portion 33 that is also the support portion has a function of maintaining the internal space, that is, the cavity portion 13 of the container 10 that is decompressed.

The support portion 23 has the third wick portion 33, and in the vapor chamber 1, the support portion 23 is composed of the third wick portion 33. The third wick portion 33 is a columnar member in side view that extends along a thickness direction of the container 10. Further, in the vapor chamber 1, the third wick portion 33 is a member that extends from the second wick portion 32 toward the first wick portion 31. The third wick portion 33 is composed of a plurality of members columnar in side view. The third wick portion 33 has a structure in which the plurality of members columnar in side view are disposed in parallel at predetermined intervals along the main surface of the container 10. In the vapor chamber 1, a space portion between the third wick portion 33 and the third wick portion 33 is the vapor flow path 15 through which the working fluid in a gas phase flows.

As shown in FIG. 2, one end 41 of the third wick portion 33 extends to the first wick portion 31, and is integrated with the first wick portion 31. In the vapor chamber 1, the one end 41 of the third wick portion 33 is joined to the first wick portion 31, and thereby the third wick portion 33 is integrated with the first wick portion 31. Further, another end 42 of the third wick portion 33 extends to the second wick portion 32, and is integrated with the second wick portion 32. In the vapor chamber 1, the third wick portion 33 and the second wick portion 32 are integrally molded, and thereby the third wick portion 33 is integrated with the second wick portion 32.

In the vapor chamber 1, a porosity of the first wick portion 31 in a part 34 that overlaps with the support portion 23 in plan view in the first wick portion 31 is in a mode of being smaller than a porosity of the first wick portion 31 in a part 35 that does not overlap with the support portion 23 in plan view.

Materials of the first wick portion 31, the second wick portion 32, and the third wick portion 33 are not particularly limited as long as the materials have a capillary force, and in the vapor chamber 1, the first wick portion 31, the second wick portion 32, and the third wick portion 33 are all sintered bodies made from powder containing metal powder having a predetermined average particle size as the materials. The sintered body made from powder containing metal powder is a porous member. As the sintered body of powder containing metal powder, it is possible to cite a sintered body of metal powder such as copper powder, and stainless steel powder, a sintered body of mixture powder of metal powder such as copper powder and carbon powder, and the like. The first wick portion 31 is a sintered body an entire body of which is formed by using the same powder material, and the second wick portion 32 is a sintered body an entire body of which is formed by using the same powder material. Further, the third wick portion 33 is a sintered body formed by using the same powder material from the one end 41 to the other end 42.

In the vapor chamber 1, the powder material of the third wick portion 33 differs from the powder material of the first wick portion 31, and the sintered body forming the third wick portion 33 has a different configuration from the sintered body forming the first wick portion 31. Further, the porosity of the third wick portion 33 has a mode of being different from the porosity of the first wick portion 31. Note that in the vapor chamber 1, the powder material of the third wick portion 33 is the same as the powder material of the second wick portion 32, and the sintered body forming the third wick portion 33 has a substantially same configuration as the sintered body forming the second wick portion 32. Further, the porosity of the third wick portion 33 is in a mode of being a substantially same porosity as the porosity of the second wick portion 32.

Magnitudes of the capillary forces of the first wick portion 31, the second wick portion 32, and the third wick portion 33 are not particularly limited, and in the vapor chamber 1, the capillary force of the first wick portion 31 is in a mode of being larger than the capillary force of the second wick portion 32. Specifically, in the vapor chamber 1, the porosity of the first wick portion 31 in the part 35 that does not overlap with the support portion 23 (that is, the third wick portion 33) in plan view is smaller than a porosity of the second wick portion 32 in a part 37 that does not overlap with the support portion 23 (that is, the third wick portion 33) in plan view in the second wick portion 32, and thereby the capillary force of the first wick portion 31 is in a mode of being larger than the capillary force of the second wick portion 32. Note that in the vapor chamber 1, the porosity of the part 37 that does not overlap with the support portion 23 in plan view in the second wick portion 32, and a porosity of a part 36 that overlaps with the support portion 23 in plan view in the second wick portion 32 are substantially the same, and the entire second wick portion 32 has a substantially same capillary force.

Further, in the vapor chamber 1, the capillary force of the first wick portion 31 is in a mode of being larger than the capillary force of the third wick portion 33. Specifically, in the vapor chamber 1, the porosity of the first wick portion 31 in the part 35 that does not overlap with the support portion 23 in plan view is smaller than the porosity of the third wick portion 33, and thereby the capillary force of the first wick portion 31 is in a mode of being larger than the capillary force of the third wick portion 33.

Note that as described above, correspondingly to the porosity of the third wick portion 33 being substantially the same as the porosity of the second wick portion 32, the capillary force of the third wick portion 33 is substantially the same as the capillary force of the second wick portion 32.

A porosity and a capillary force of a sintered body of powder containing metal powder are adjustable by properly setting an average particle size of the powder material. By reducing the average particle size of the powder material, it is possible to reduce the porosity of the sintered body of the powder containing metal powder, and thus, it is possible to increase a capillary force of the aforementioned sintered body. On the other hand, by increasing the average particle size of the powder material, it is possible to increase the porosity of the sintered body of powder containing metal powder, and thus, it is possible to reduce a capillary force of the aforementioned sintered body.

The vapor flow path 15 is an internal space of the container 10, and extends throughout the entire container 10. Accordingly, the working fluid in a gas phase can flow throughout the entire container 10 by the vapor flow path 15.

A material of the container 10 is not particularly limited, and for example, copper, a copper alloy, aluminum, an aluminum alloy, tin, a tin alloy, titanium, a titanium alloy, nickel, a nickel alloy and the like are cited. Further, the working fluid enclosed in the inside of the container 10 can be properly selected according to the material of the container 10, and it is possible to cite, for example, water, CFC substitute, perfluorocarbon, cyclopentane, ethylene glycol, mixtures of these with water.

Next, an example of a method for manufacturing the vapor chamber 1 according to the first embodiment will be described. First, powder containing metal powder having a predetermined average particle size is applied to an inner surface of the one plate-shaped body 11, which is sintered thereafter to form a sintered body that is the first wick portion 31. In addition, powder containing metal powder having a predetermine average particle size is applied to the inner surface of the other plate-shaped body 12, which is sintered thereafter to form a sintered body in which the third wick portion 33 and the second wick portion 32 are integrally molded. Thereafter, by overlapping the one plate-shaped body 11 and the other plate-shaped body 12 with each other so that a tip end of the third wick portion 33 and the first wick portion 31 face each other, and sintering the one plate-shaped body 11 and the other plate-shaped body 12, the third wick portion 33 is joined to and integrated with the first wick portion 31 to be able to manufacture the vapor chamber 1. In manufacturing the vapor chamber 1, by making a height of the third wick portion 33 based on the inner surface of the other plate-shaped body 12 slightly higher than a dimension obtained by removing a thickness of the first wick portion 31 from a thickness of the cavity portion 13, the porosity of the first wick portion 31 in the part 34 that overlaps with the support portion 23 in plan view in the first wick portion 31 is in a mode of being smaller than the porosity of the first wick portion 31 in the part 35 that does not overlap with the support portion 23 in plan view.

Next, an operation of the vapor chamber 1 according to the first embodiment of the present disclosure will be described. In the container 10, the heating element 100 is thermally connected to the outer surface of the first surface 21, the first surface 21 functions as a heat receiving surface, and in the outer surface of the first surface 21, a part in contact with the heating element 100 functions as a heat receiving portion. When the vapor chamber 1 receives heat from the heating element 100 in the heat receiving portion, the working fluid in a liquid phase enclosed in the cavity portion 13 changes in phase from a liquid phase to a gas phase in the heat receiving portion, and the working fluid in a gas phase that changes in phase flows through the vapor flow path 15 to diffuse throughout the entire cavity portion 13 from the heat receiving portion of the vapor chamber 1. The working fluid in a gas phase that diffuses throughout the entire cavity portion 13 from the heat receiving portion releases latent heat, and changes in phase from a gas phase to a liquid phase. At this time, the released latent heat is released to an external environment of the vapor chamber 1 from the entire container 10. The working fluid that changes in phase from a gas phase to a liquid phase flows back to the first wick portion 31 via the third wick portion 33 from the second wick portion 32, and the working fluid in a liquid phase in the first wick portion 31 flows back to the part in the first wick portion 31 corresponding to the heat receiving portion from an entire region of the first wick portion 31 by the capillary force of the first wick portion 31.

In the vapor chamber 1, the one end 41 of the third wick portion 33 of the support portion 23 is integrated with the first wick portion 31 provided on the first surface 21, and the other end 42 of the third wick portion 33 of the support portion 23 is integrated with the second wick portion 32 provided on the second surface 22, whereby the first surface 21 and the second surface 22 of the container 10 are both fixed to the support portion 23. Accordingly, the vapor chamber 1 not only has resistance to pressure from the external environment such as atmospheric pressure, but also is excellent in resistance to pressure from the inside of the vapor chamber 1, so that even if the temperature of the usage environment rises and vaporization of the working fluid is promoted, the vapor chamber 1 can be prevented from expanding, and can exhibit excellent deformation resistance.

Further, as shown in FIG. 3, the one end 41 of the third wick portion 33 of the support portion 23 is integrated with the first wick portion 31 provided on the first surface, and thereby interface formation between the first wick portion 31 and the third wick portion 33 is prevented. Further, the other end 42 of the third wick portion 33 of the support portion 23 is integrated with the second wick portion 32 provided on the second surface, and thereby interface formation between the second wick portion 32 and the third wick portion 33 is prevented. Accordingly, reflux characteristics of a working fluid L in a liquid phase from the second wick portion 32 to the third wick portion 33 and reflux characteristics of the working fluid L in a liquid phase from the third wick portion 33 to the first wick portion 31 are improved, and therefore heat transport properties of the vapor chamber 1 are improved.

Further, in the vapor chamber 1, the porosity of the first wick portion 31 in the part 34 that overlaps with the third wick portion 33 that is the support portion 23 in plan view is smaller than the porosity of the first wick portion 31 in the part 35 that does not overlap with the third wick portion 33 that is the support portion 23 in plan view, and thereby it is possible to make a connection area of the third wick portion 33 and the first wick portion 31 in a mode of being increased, so that integration of the third wick portion 33 and the first wick portion 31 is enhanced, and it is possible to obtain more excellent deformation resistance.

Further, in the vapor chamber 1, the first wick portion 31, the second wick portion 32, and the third wick portion 33 are all sintered bodies of powder containing metal powder, and thereby integration of the third wick portion 33 and the first wick portion 31, and integration of the third wick portion 33 and the second wick portion 32 are reliably enhanced.

Further, in the vapor chamber 1, by composing the support portion 23 of the third wick portion 33, the reflux characteristics of the working fluid in a liquid phase from the second wick portion 32 to the first wick portion 31 are further improved.

Next, a vapor chamber according to a second embodiment of the present disclosure will be described in detail. The vapor chamber according to the second embodiment shares main components with the vapor chamber according to the first embodiment, and therefore the same components as the components of the vapor chamber according to the first embodiment will be described by using the same reference signs. FIG. 4 is a sectional side view explaining an outline of an internal structure of the vapor chamber according to the second embodiment of the present disclosure. Note that an arrow P in the drawing indicates a direction of plan view.

In the vapor chamber 1 according to the first embodiment, the one end 41 of the third wick portion 33 is joined to the first wick portion 31, and thereby the third wick portion 33 is integrated with the first wick portion 31, but as shown in FIG. 4, in a vapor chamber 2 according to the second embodiment, a third wick portion 33 is integrally molded with a first wick portion 31 provided on a first surface 21 to which a heating element 100 is thermally connected, whereby the third wick portion 33 is integrated with the first wick portion 31. Further, in the vapor chamber 1 according to the first embodiment, the third wick portion 33 is integrated with the second wick portion 32 by the third wick portion 33 being integrally molded with the second wick portion 32, but as shown in FIG. 4, in the vapor chamber 2 according to the second embodiment, another end 42 of the third wick portion 33 is joined to a second wick portion 32 of a second surface 22, and thereby the third wick portion 33 is integrated with the second wick portion 32.

In the vapor chamber 2, in the second wick portion 32, a porosity of the second wick portion 32 in a part 36 that overlaps with a support portion 23 in plan view is in a mode of being smaller than a porosity of the second wick portion 32 in a part 37 that does not overlap with the support portion 23 in plan view.

In the vapor chamber 1 according to the first embodiment, the porosity of the third wick portion 33 is substantially the same as the porosity of the second wick portion 32, but in the vapor chamber 2, a porosity of the third wick portion 33 differs from a porosity of the second wick portion 32. A powder material of the third wick portion 33 differs from a powder material of the second wick portion 32, and a sintered body forming the third wick portion 33 has a different configuration from a configuration of a sintered body that forms the second wick portion 32. Note that in the vapor chamber 2, the powder material of the third wick portion 33 is the same as a powder material of the first wick portion 31, and the sintered body forming the third wick portion 33 has a substantially same configuration as a sintered body that forms the first wick portion 31. Further, the porosity of the third wick portion 33 is in a mode of being substantially the same as a porosity of the first wick portion 31. From the above, a capillary force of the third wick portion 33 is substantially the same as a capillary force of the first wick portion 31.

In the vapor chamber 2, the porosity of the third wick portion 33 is in a mode of being smaller than the porosity of the second wick portion 32 in the part 37 that does not overlap with the support portion 23 in plan view. From the above, the capillary force of the third wick portion 33 is in a mode of being larger than a capillary force of the second wick portion 32 in the part 37 that does not overlap with the support portion 23 in plan view.

Since in the vapor chamber 2, one end 41 of the support portion 23 is integrated with the first wick portion 31 provided on the first surface 21, and the other end 42 of the support portion 23 is integrated with the second wick portion 32 provided on the second surface 22, whereby the vapor chamber 2 not only has resistance to pressure from an external environment such as atmospheric pressure, but also is excellent in resistance to pressure from an inside of the vapor chamber 2, so that even if the temperature of a usage environment rises and vaporization of the working fluid is promoted, the vapor chamber 2 can be prevented from expanding, and can exhibit excellent deformation resistance.

Further, since in the vapor chamber 2, interface formation between the first wick portion 31 and the third wick portion 33 is also prevented, and interface formation between the second wick portion 32 and the third wick portion 33 is also prevented, reflux characteristics of the working fluid in a liquid phase from the second wick portion 32 to the third wick portion 33 and reflux characteristics of the working fluid in a liquid phase from the third wick portion 33 to the first wick portion 31 are improved, so that heat transport properties of the vapor chamber 2 are improved.

Further, in the vapor chamber 2, the porosity of the second wick portion 32 in the part 36 that overlaps with the support portion 23 in plan view is smaller than the porosity of the second wick portion 32 in the part 37 that does not overlap with the support portion 23 in plan view, and thereby it is possible to make a connection area of the third wick portion 33 of the support portion 23 and the second wick portion 32 in a mode of being increased, so that integration of the third wick portion 33 and the second wick portion 32 is enhanced, and it is possible to obtain more excellent deformation resistance.

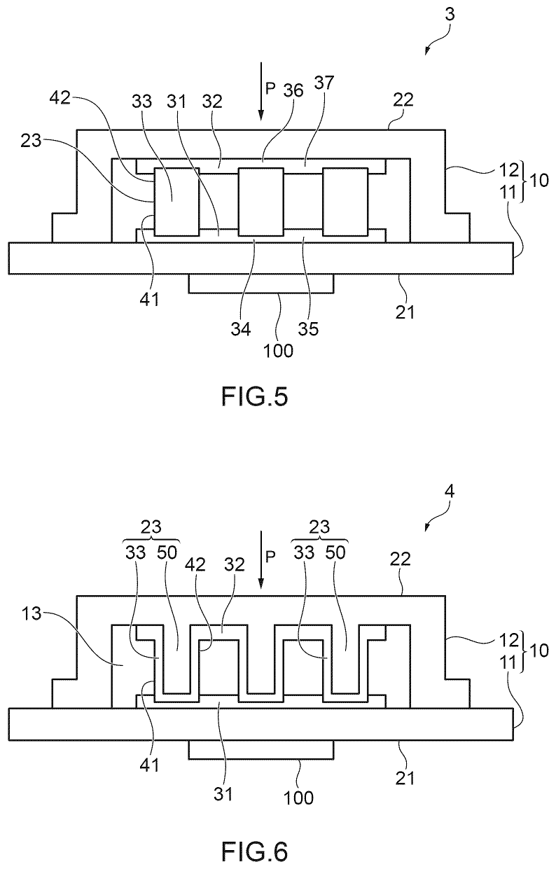

Next, details of a vapor chamber according to a third embodiment of the present disclosure will be described. Since the vapor chamber according to the third embodiment shares main components with the vapor chambers according to the first and second embodiments, the same components as the components of the vapor chambers according to the first and second embodiments will be described by using the same reference signs. FIG. 5 is a sectional side view explaining an outline of an internal structure of the vapor chamber according to the third embodiment of the present disclosure. Note that an arrow P in the drawing indicates a direction of plan view.

As shown in FIG. 5, in the vapor chamber 3 according to the third embodiment, one end 41 of a third wick portion 33 is joined to a first wick portion 31 of a first surface 21, whereby the third wick portion 33 is integrated with the first wick portion 31, and another end 42 of the third wick portion 33 is joined to a second wick portion 32 of a second surface 22, whereby the third wick portion 33 is integrated with the second wick portion 32. In the vapor chamber 3, the third wick portion 33 is not integrally molded with the first wick portion 31 and is not integrally molded with the second wick portion 32, either.

In the vapor chamber 3, in the first wick portion 31, a porosity of the first wick portion 31 in a part 34 that overlaps with a support portion 23 in plan view is in a mode of being smaller than a porosity of the first wick portion 31 in a part 35 that does not overlap with the support portion 23 in plan view. Further, in the second wick portion 32, a porosity of the second wick portion 32 in a part 36 that overlaps with the support portion 23 in plan view is in a mode of being smaller than a porosity of the second wick portion 32 in a part 37 that does not overlap with the support portion 23 in plan view.

In the vapor chamber 3, a porosity of the third wick portion 33 differs from a porosity of the first wick portion 31, and differs from a porosity of the second wick portion 32. A powder material of the first wick portion 31, a powder material of the second wick portion 32, and a powder material of the third wick portion 33 differ from one another, and a sintered body forming the first wick portion 31, a sintered body forming the second wick portion 32, and a sintered body forming the third wick portion 33 have different configurations from one another. In the vapor chamber 3, the porosity of the first wick portion 31 is in a mode of being smaller than the porosity of the third wick portion 33, and the porosity of the third wick portion 33 is in a mode of being smaller than the porosity of the second wick portion 32. From the above, in the vapor chamber 3, a capillary force of the first wick portion 31 is larger than a capillary force of the third wick portion 33, and the capillary force of the third wick portion 33 is in a mode of being larger than a capillary force of the second wick portion 32.

In the vapor chamber 3, the one end 41 of the support portion 23 is also integrated with the first wick portion 31 provided on the first surface 21, and the other end 42 of the support portion 23 is also integrated with the second wick portion 32 provided on the second surface 22, whereby the vapor chamber 3 not only has resistance to pressure from an external environment such as atmospheric pressure, but also is excellent in resistance to pressure from an inside of the vapor chamber 3, so that even if a temperature of a usage environment rises and vaporization of a working fluid is promoted, the vapor chamber 3 can be prevented from expanding, and can exhibit excellent deformation resistance.

Further, since in the vapor chamber 3, interface formation between the first wick portion 31 and the third wick portion 33 is also prevented, and interface formation between the second wick portion 32 and the third wick portion 33 is also prevented, reflux characteristics of the working fluid in a liquid phase from the second wick portion 32 to the third wick portion 33 and reflux characteristics of the working fluid in a liquid phase from the third wick portion 33 to the first wick portion 31 are improved, so that heat transport properties of the vapor chamber 3 are improved.

Next, a vapor chamber according to a fourth embodiment of the present disclosure will be described in detail. Since the vapor chamber according to the fourth embodiment shares main components with the vapor chamber according to the first to third embodiments, the same components as the components of the vapor chambers according to the first to third embodiments will be described by using the same reference signs. FIG. 6 is a sectional side view explaining an outline of an internal structure of the vapor chamber according to the fourth embodiment of the present disclosure. Note that an arrow P in the drawing indicates a direction of plan view.

In the vapor chamber 1 according to the first embodiment, the support portion 23 is composed of the third wick portion 33, but instead of this, as shown in FIG. 6, in a vapor chamber 4 according to the fourth embodiment, a support portion 23 is formed of a protruding part 50 protruding in a direction of a cavity portion 13 from a second surface 22, and a third wick portion 33 covering a surface of the protruding part 50. The protruding part 50 is formed on the second surface 22, and protrudes in a direction of a first surface 21 from the second surface 22. The protruding part 50 is a solid metal member. As the metal member of the protruding part 50, it is possible to cite a same metal member as the metal member of the container 10.

The protruding part 50 may be integrally molded with the second surface 22, or may be a separate member from the second surface 22. In the vapor chamber 4, the protruding part 50 is integrally molded with the second surface 22.

A part of the third wick portion 33 positioned at one end 41 of the support portion 23 is joined to a first wick portion 31, and thereby the third wick portion 33 is integrated with the first wick portion 31. Further, the third wick portion 33 and a second wick portion 32 are integrally molded, and thereby the third wick portion 33 is integrated with the second wick portion 32.

In the vapor chamber 4, the one end 41 of the support portion 23 is also integrated with the first wick portion 31 provided on the first surface 21, and another end 42 of the support portion 23 is also integrated with the second wick portion 32 provided on the second surface 22, and thereby the vapor chamber 4 not only has resistance to pressure from an external environment such as atmospheric pressure, but also is excellent in resistance to pressure from an inside of the vapor chamber 4, so that even if a temperature of a usage environment rises and vaporization of a working fluid is promoted, the vapor chamber 4 can be prevented from expanding, and can exhibit excellent deformation resistance.

Further, in the vapor chamber 4, interface formation between the first wick portion 31 and the third wick portion 33 is also prevented, and interface formation between the second wick portion 32 and the third wick portion 33 is also prevented, and thereby reflux characteristics of a working fluid in a liquid phase from the second wick portion 32 to the third wick portion 33 and reflux characteristics of the working fluid in a liquid phase from the third wick portion 33 to the first wick portion 31 are improved, so that heat transport properties of the vapor chamber 4 are improved.

Further, since in the vapor chamber 4, the support portion 23 is formed of the protruding part 50 protruding in the direction of the cavity portion 13 from the second surface 22 and the third wick portion 33 covering the surface of the protruding part 50, it is possible to further improve deformation resistance of the vapor chamber 4 while improving the reflux characteristics of the working fluid in a liquid phase from the second wick portion 32 to the first wick portion 31.

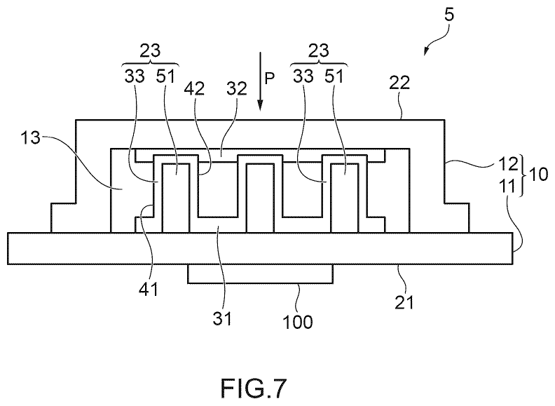

Next, a vapor chamber according to a fifth embodiment of the present disclosure will be described in detail. Since the vapor chamber according to the fifth embodiment shares main components with the vapor chambers according to the first to fourth embodiments, the same components as the components of the vapor chambers according to the first to fourth embodiments will be described by using the same reference signs. FIG. 7 is a sectional side view explaining an outline of an internal structure of the vapor chamber according to the fifth embodiment of the present disclosure. Note that an arrow P in the drawing indicates a direction of plan view.

In the vapor chamber 2 according to the second embodiment, the support portion 23 is composed of the third wick portion 33, but instead of this, as shown in FIG. 7, in a vapor chamber 5 according to the fifth embodiment, a support portion 23 is formed of a protruding part 51 protruding in a direction of a cavity portion 13 from a first surface 21, and a third wick portion 33 covering a surface of the protruding part 51. The protruding part 51 is formed on the first surface 21, and protrudes in a direction of a second surface 22 from the first surface 21. The protruding part 51 is a solid metal member. As the metal member of the protruding part 51, it is possible to cite a same metal member as the metal member of a container 10.

The protruding part 51 may be integrally molded with the first surface 21, or may be a separate member from the first surface 21. In the vapor chamber 5, the protruding part 51 is a separate member from the first surface 21.

A part of the third wick portion 33 positioned at another end 42 of the support portion 23 is joined to a second wick portion 32, and thereby the third wick portion 33 is integrated with the second wick portion 32. Further, the third wick portion 33 and a first wick portion 31 are integrally molded, and thereby the third wick portion 33 is integrated with the first wick portion 31.

In the vapor chamber 5, one end 41 of the support portion 23 is also integrated with the first wick portion 31 provided on the first surface 21, and the other end 42 of the support portion 23 is integrated with the second wick portion 32 provided on the second surface 22, and thereby the vapor chamber 5 not only has resistance to pressure from an external environment such as atmospheric pressure, but also is excellent in resistance to pressure from an inside of the vapor chamber 5, so that even if a temperature of a usage environment rises and vaporization of a working fluid is promoted, the vapor chamber 5 can be prevented from expanding, and can exhibit excellent deformation resistance.

Further, since in the vapor chamber 5, interface formation between the first wick portion 31 and the third wick portion 33 is also prevented, and interface formation between the second wick portion 32 and the third wick portion 33 is also prevented, reflux characteristics of a working fluid in a liquid phase from the second wick portion 32 to the third wick portion 33 and reflux characteristics of the working fluid in a liquid phase from the third wick portion 33 to the first wick portion 31 are improved, so that heat transport properties of the vapor chamber 5 is improved.

Further, since in the vapor chamber 5, the support portion 23 is formed of the protruding part 51 protruding in the direction of the cavity portion 13 from the first surface 21 and the third wick portion 33 covering the surface of the protruding part 51, it is possible to further improve deformation resistance of the vapor chamber 5 while improving the reflux characteristics of the working fluid in a liquid phase from the second wick portion 32 to the first wick portion 31.

The vapor chamber of the present disclosure not only has resistance to the pressure from the external environment, but also is excellent in resistance to the pressure from the inside of the vapor chamber, so that the vapor chamber can be prevented from expanding, and therefore has a high utility value in the field of cooling a heating element installed in an environment with a high ambient temperature.

What is claimed is:

1. A vapor chamber comprising:
a container having a cavity portion formed inside, and having a first surface to which a heating element is to be thermally connected and a second surface facing the first surface;
a first wick portion provided on the first surface in an inside of the container;
a second wick portion provided on the second surface in the inside of the container;
a support portion having a third wick portion, protruding in a direction to connect the first surface and the second surface in the inside of the container;
a working fluid enclosed in the cavity portion; and
a vapor flow path through which the working fluid in a gas phase is to flow, the vapor flow path being provided in the cavity portion,
wherein one end of the third wick portion is integrated with the first wick portion, and another end of the third wick portion is integrated with the second wick portion, whereby the first surface and the second surface of the container are fixed to the support portion, and
a porosity of the first wick portion in a part that overlaps with the support portion in plan view is smaller than a porosity of the first wick portion in a part that does not overlap with the support portion in plan view.

2. A vapor chamber comprising:
a container having a cavity portion formed inside, and having a first surface to which a heating element is to be thermally connected and a second surface facing the first surface;
a first wick portion provided on the first surface in an inside of the container;
a second wick portion provided on the second surface in the inside of the container;
a support portion having a third wick portion, protruding in a direction to connect the first surface and the second surface in the inside of the container;
a working fluid enclosed in the cavity portion; and
a vapor flow path through which the working fluid in a gas phase is to flow, the vapor flow path being provided in the cavity portion,
wherein one end of the third wick portion is integrated with the first wick portion, and another end of the third wick portion is integrated with the second wick portion, whereby the first surface and the second surface of the container are fixed to the support portion, and
a porosity of the second wick portion in a part that overlaps with the support portion in plan view is smaller than a porosity of the second wick portion in a part that does not overlap with the support portion in plan view.

3. The vapor chamber according to claim 1, wherein the first wick portion, the second wick portion, and the third wick portion are sintered bodies of powder containing metal powder.

4. The vapor chamber according to claim 2, wherein the first wick portion, the second wick portion, and the third wick portion are sintered bodies of powder containing metal powder.

5. The vapor chamber according to claim 1, wherein the support portion comprises the third wick portion.

6. The vapor chamber according to claim 2, wherein the support portion comprises the third wick portion.

7. The vapor chamber according to claim 1, wherein the support portion is formed of a protruding part protruding in a direction of the cavity portion from the first surface or a protruding part protruding in the direction of the cavity portion from the second surface, and the third wick portion covering a surface of the protruding part.

8. The vapor chamber according to claim 2, wherein the support portion is formed of a protruding part protruding in a direction of the cavity portion from the first surface or a protruding part protruding in the direction of the cavity portion from the second surface, and the third wick portion covering a surface of the protruding part.

9. The vapor chamber according to claim 7, wherein the protruding part is solid.

10. The vapor chamber according to claim 8, wherein the protruding part is solid.

11. A vapor chamber comprising:
a container having a cavity portion formed inside, and having a first surface to which a heating element is to be thermally connected and a second surface facing the first surface;
a first wick portion provided on the first surface in an inside of the container;
a second wick portion provided on the second surface in the inside of the container;
a support portion having a third wick portion, protruding in a direction to connect the first surface and the second surface in the inside of the container;
a working fluid enclosed in the cavity portion; and
a vapor flow path through which the working fluid in a gas phase is to flow, the vapor flow path being provided in the cavity portion,
wherein one end of the third wick portion is integrated with the first wick portion, and another end of the third wick portion is integrated with the second wick portion, and
a porosity of the first wick portion in a part that does not overlap with the support portion in plan view is smaller than a porosity of the second wick portion in a part that does not overlap with the support portion in plan view.

12. A vapor chamber comprising:
a container having a cavity portion formed inside, and having a first surface to which a heating element is to be thermally connected and a second surface facing the first surface;
a first wick portion provided on the first surface in an inside of the container;
a second wick portion provided on the second surface in the inside of the container;
a support portion having a third wick portion protruding in a direction to connect the first surface and the second surface in the inside of the container;
a working fluid enclosed in the cavity portion; and
a vapor flow path through which the working fluid in a gas phase is to flow, the vapor flow path being provided in the cavity portion,
wherein one end of the third wick portion is integrated with the first wick portion, and another end of the third wick portion is integrated with the second wick portion, and
a porosity of the first wick portion in a part that does not overlap with the support portion in plan view is smaller than a porosity of the third wick portion.

13. A vapor chamber comprising:
a container having a cavity portion formed inside, and having a first surface to which a heating element is to be thermally connected and a second surface facing the first surface;
a first wick portion provided on the first surface in an inside of the container;
a second wick portion provided on the second surface in the inside of the container;
a support portion having a third wick portion, protruding in a direction to connect the first surface and the second surface in the inside of the container;
a working fluid enclosed in the cavity portion; and
a vapor flow path through which the working fluid in a gas phase is to flow, the vapor flow path being provided in the cavity portion,
wherein one end of the third wick portion is integrated with the first wick portion, and another end of the third wick portion is integrated with the second wick portion, and
a porosity of the third wick portion is smaller than a porosity of the second wick portion in a part that does not overlap with the support portion in plan view.

14. The vapor chamber according to claim 1, wherein a porosity of the third wick portion differs from a porosity of the first wick portion or a porosity of the second wick portion.

15. The vapor chamber according to claim 2, wherein a porosity of the third wick portion differs from a porosity of the first wick portion or a porosity of the second wick portion.

16. The vapor chamber according to claim 1, wherein a porosity of the third wick portion differs from a porosity of the first wick portion and differs from a porosity of the second wick portion.

17. The vapor chamber according to claim 2, wherein a porosity of the third wick portion differs from a porosity of the first wick portion and differs from a porosity of the second wick portion.
